(19) United States
(12) Patent Application Publication
(10) Pub. No.: US 2012/0073626 A1
(43) Pub. Date: Mar. 29, 2012

(54) LIGHT CONCENTRATOR ASSEMBLY AND SOLAR CELL APPARATUS HAVING SAME

(75) Inventors: YU-SHU CHEN, Chu-Nan (TW); KUO-FENG CHIANG, Chu-Nan (TW); CHIEN-TING LU, Chu-Nan (TW); KUO-MANG LO, Chu-Nan (TW); YING-CHING CHEN, Chu-Nan (TW); ZHENG-JAY HUANG, Chu-Nan (TW)

(73) Assignee: FOXSEMICON INTEGRATED TECHNOLOGY, INC., Chu-Nan (TW)

(21) Appl. No.: 13/241,070

(22) Filed: Sep. 22, 2011

(30) Foreign Application Priority Data
Sep. 24, 2010 (TW) 099132267

(51) Int. Cl. H01L 31/052; H01L 31/0232; G02B 3/08

(52) U.S. Cl. 136/246; 359/742; 136/259

(57) ABSTRACT

A light concentrator assembly includes a first Fresnel lens, a second Fresnel lens, and a compound parabolic concentrator. The first Fresnel lens includes a first flat surface and an opposite first Fresnel lens surface. The second Fresnel lens includes a second flat surface and an opposite second Fresnel lens surface facing the first Fresnel lens surface. A first focal point of the first Fresnel lens and a second focal point of the second Fresnel lens coincide. The compound parabolic concentrator is located opposite the second flat surface. Light beams are converged by the first and second Fresnel lenses, and exit through the compound parabolic concentrator.

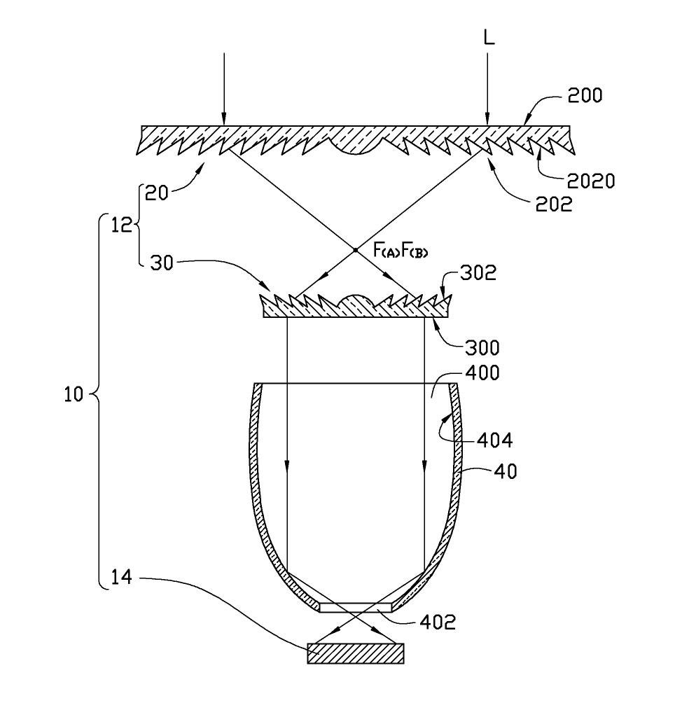

### BACKGROUND

1. Technical Field

The present disclosure relates to a light concentrator assembly and a related solar cell apparatus.

2. Description of Related Art

Many solar cell apparatuses use reflectors to reflect light to the solar cell, or use convex lenses to converge light onto the solar cell. However, the reflectors and convex lenses do not provide both great light concentration uniformity and great light concentration efficiency, and so the solar cell cannot be fully excited to work at its full potential.

What is needed, therefore, is a light concentrator assembly and a solar cell apparatus with same, which can overcome the above shortcomings.

### BRIEF DESCRIPTION OF THE DRAWINGS

Many aspects of the light concentrator assembly and solar cell apparatus can be better understood with reference to the following drawings. The components in the drawings are not necessarily drawn to scale, the emphasis instead being placed upon clearly illustrating the principles of the present light concentrator assembly and solar cell apparatus. Moreover, in the drawings, like reference numerals designate corresponding parts throughout the several views.

The FIGURE shows a schematic, cross-sectional view of a solar cell apparatus in accordance with an embodiment, the solar cell apparatus including a light concentrator assembly and a solar cell device.

### DETAILED DESCRIPTION

Embodiments of the present light concentrator assembly and solar cell apparatus will now be described in detail below and with reference to the drawings.

Referring to the FIGURE, a solar cell apparatus 10 includes a light concentrator assembly 12 and a solar cell device 14.

The light concentrator assembly 12 includes a first Fresnel lens 20, a second Fresnel lens 30, and a compound parabolic concentrator (CPC) 40.

The first Fresnel lens 20 includes a first flat surface 200 and an opposite first Fresnel lens surface 202. The first Fresnel lens surface 202 includes a set of concentric annular sections 2020 known as “Fresnel zones”. The first Fresnel lens 20 includes a first focal point F(A) at an side of the first Fresnel lens surface 202. The first Fresnel lens 20 is used to converge the light beams L at the first focal point F(A).

The second Fresnel lens 30 includes a second flat surface 300 and an opposite second Fresnel lens surface 302. The second Fresnel lens surface 302 also includes a set of Fresnel zones. The second Fresnel lens 30 is smaller than the first Fresnel lens 20 and the second Fresnel lens 30 has a smaller focal length than the first Fresnel lens 20. The second Fresnel lens 30 is located to be substantially parallel with the first Fresnel lens 20. The second Fresnel lens surface 302 faces the first Fresnel lens surface 202. The second Fresnel lens 30 has a second focal point F(B) at an side of the second Fresnel lens surface 302. The second and first focal points F(A) and F(B) coincide such that original parallel incident light beams L may be converged to the first focal point F(A) and then to be parallel output light beams incident the CPC 40. The second Fresnel lens 30 converge the scattered light beams from the first focal point F(A) to be parallel incident light beams incident on a parabolic surface 404 (described below).

The CPC 40 includes a light incident opening 400, an opposite light output opening 402, and the parabolic surface 404 located between the light incident opening 400 and the light output opening 402. The CPC 40 is located beneath and aligned with the second Fresnel lens 30. The light incident opening 400 may be the same size as the second Fresnel lens 30.

The CPC 40 has an acceptance angle. If the incident angle of the incident light beams is equal to or smaller than the acceptable angle, the incident light beams will be reflected by the parabolic surface 404 to exit through the light output opening 402. If the incident angle is larger than the acceptable angle, the incident light beams will be finally reflected out of the CPC 40 from the light incident opening 400. Because the size and the focal length of the second Fresnel lens 30 are smaller than those of the first Fresnel lens 20, the output parallel light beams have a smaller beam diameter than the original parallel incident light beams L, and the incident angle of the output parallel light beams will be smaller than before. More light beams enter the CPC 40 to be converged, therefore the concentration efficiency of the light concentrator assembly 12 is relatively increased.

In this embodiment, an axis (not shown) of the compound parabolic concentrator 40 coincide with an axes of the first and second Fresnel lens 20 and 30 to maximize the concentration efficiency.

The solar cell device 14 is aligned with the light output opening 402 to receive the output parallel light from the light concentrator assembly 10. The solar cell device 14 may have one or more solar cells to convert the light energy to electrical energy. The solar cells device 14 may be attached to the light output opening 402, or under the light output opening 402. The solar cell device 14 may be the same size as the light output opening 402.

It is understood that the above-described embodiments are intended to illustrate rather than limit the disclosure. Variations may be made to the embodiments without departing from the spirit of the disclosure. Accordingly, it is appropriate that the appended claims be construed broadly and in a manner consistent with the scope of the disclosure.

What is claimed is:

1. A light concentrator assembly comprising:
a first Fresnel lens comprising a first flat surface and an opposite first Fresnel lens surface, the first Fresnel lens configured to converge parallel incident light beams at a first focal point thereof;
a second Fresnel lens comprising a second flat surface and an opposite second Fresnel lens surface, wherein the second Fresnel lens surface faces the first Fresnel lens surface, the second Fresnel lens has a second focal point coinciding with the first focal point, and a size of second Fresnel lens is smaller than that of the first Fresnel lens; and
a compound parabolic concentrator comprising a light incident opening, an opposite light output opening, and a parabolic surface located between the light incident opening and the light output opening, the compound parabolic concentrator aligned with the first and second Fresnel lenses, the second Fresnel lens configured to converge the light beams from the first Fresnel lens, the parabolic surface configured to reflect and direct the light beams from the second Fresnel lens to exit through the light output opening.

2. The light concentrator assembly of claim 1, wherein the light incident opening has the same size as that of the second Fresnel lens.

3. The light concentrator assembly of claim 1, wherein the size of the light incident opening is larger than that of the light output opening.

4. A solar cell apparatus, comprising:
a first Fresnel lens comprising a first flat surface and an opposite first Fresnel lens surface, the first Fresnel lens configured to converge parallel incident light beams at a first focal point thereof;
a second Fresnel lens comprising a second flat surface and an opposite second lens surface, wherein the first and second flat surfaces are parallel to each other, the second lens surface faces the first lens surface, the second Fresnel lens has a second focal point coinciding with the first focal point, the second Fresnel lens configured to converge the light beams from the first Fresnel lens, a size of second Fresnel lens is smaller than that of the first Fresnel lens;
a compound parabolic concentrator comprising a light incident opening, an opposite light output opening, and a parabolic surface located between the light incident opening and the light output opening, the second flat surface facing the compound parabolic concentrator, the parabolic surface configured to reflect and direct the light beams from the second Fresnel lens to exit through the light output opening; and
a solar cell device aligned with the light output opening.

5. The solar cell apparatus of claim 5, wherein the solar cell device comprises a single solar cell or an array of solar cells.

6. The solar cell apparatus of claim 5, wherein the solar cell device is attached to the light output opening.

7. The solar cell apparatus of claim 5, wherein the solar cell device has the same size as the light output opening.
